(19) United States
(12) Patent Application Publication
(10) Pub. No.: US 2010/0224900 A1
(43) Pub. Date: Sep. 9, 2010

(54) SEMICONDUCTOR OPTOELECTRONIC DEVICE AND METHOD FOR MAKING THE SAME

(75) Inventors: PENG YI WU, TAICHUNG CITY (TW); SHIH CHENG HUANG, HSINCHU CITY (TW); CHIH PANG MA, TAOYUAN COUNTY (TW); PO MIN TU, CHIAYI COUNTY (TW); YING CHAO YEH, TAIPEI COUNTY (TW); WEN YU LIN, TAICHUNG COUNTY (TW); SHIH HSIUNG CHAN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/717,671

(22) Filed: Mar. 4, 2010

(30) Foreign Application Priority Data
Mar. 6, 2009 (TW) 098107255

(51) Int. Cl. H01L 33/44

(52) U.S. Cl. 257/98; 438/29; 257/E33.061

(57) ABSTRACT

A semiconductor optoelectronic device with enhanced light extraction efficiency includes a major luminescent area and a secondary luminescent area, wherein the major luminescent area is surrounded by a secondary luminescent area. The secondary luminescent area not only can improve the light extraction efficiency of the major luminescent area, but per se also can luminesce. In addition, one embodiment of the present invention provides a fabricating method for forming the secondary luminescent area.

### BACKGROUND OF THE INVENTION

1. Field of the Invention

The present invention relates to a semiconductor optoelectronic device and a method of making the same, and relates more particularly to a semiconductor optoelectronic device having a plurality of holes and a method of fabricating the same.

2. Description of the Related Art

Light emitting diodes are electronic devices, which can convert electricity into light and have diode characteristics. Particularly, light emitting diodes only emit light when voltage is applied to their positive electrodes, and can emit stable light when direct current is supplied; however, light emitting diodes blink when alternating current is supplied, and the blinking frequency is determined by the frequency of the alternating current. The lighting theory of light emitting diodes is that electrons and holes in semiconductor material combine to produce light under an externally applied voltage.

Light emitting diodes have significant advantages of long lifespan, low heat generation, low electricity consumption, energy conservation, and pollution reduction. Light emitting diodes are widely adopted; however, their low light emitting efficiency is one problem that still needs to be improved.

Due to total reflection and transverse wave propagation phenomena, light generated by current light emitting diodes cannot be completely extracted.

Taking the example of light emitting diodes based on gallium nitride, the refractive index of the gallium nitride is 2.5, and that of air is 1. Assuming that light passes through a uniform optical surface, the calculated critical angle of total reflection is 23.5 degrees. When the incident angle of the light from the luminescent layer of a GaN light emitting diode is greater than 23.5 degrees, the light is completely reflected back to the interior of the GaN light emitting diode. Many techniques have been developed to try to improve light extraction efficiency, including a surface microstructure processing method that has been shown to be effective.

A paper titled “Light Output Improvement of InGaN-Based Light-Emitting Diodes by Microchannel Structure,” IEEE PHOTONICS TECHNOLOGY LETTERS, VOL. 19, NO. 15, Aug. 1, 200, and a paper titled “III-Nitride-Based Microarray Light-Emitting Diodes with Enhanced Light Extraction Efficiency,” Japanese Journal of Applied Physics, Vol. 47, No. 8, 2008, pp. 6757-6759 disclose methods to improve the light extraction efficiency of a semiconductor optoelectronic device. A pattern with cylindrical pillars is formed on the light-emitting region of the device, and the etched depth of the pattern may affect the light extraction efficiency of the device. FIGS. 1A and 1B respectively show two devices with light-emitting regions etched to different depths. Compared to methods in which the pattern is etched into a p-type contact layer, the luminescent intensity of a device can be increased about 40% when the pattern on the light-emitting region is etched into an n-type contact layer due to improved light extraction efficiency. However, because the light-emitting region is etched, the size of the light-emitting area is reduced.

Taiwan Patent Application No. 200701521, U.S. Pat. No. 6,953,952 B2, U.S. Pat. No. 7,358,544 B2, and U.S. Patent Application No. 2007/0228393 disclose a plurality of protrusions formed at the periphery of and around a luminescent area. The protrusion has a height similar to that of the luminescent area, and the angle of the protrusion is between approximately 30 and 80 degrees so as to avoid total reflection. FIG. 2 is a top view showing a traditional semiconductor optoelectronic device of a coplanar electrode configuration. In FIG. 2, a p-type electrode 114 is formed on a luminescent area 121, and an n-type electrode 113 is formed beside the luminescent area 110. A plurality of protrusions 119 are on the device-dicing surface 118, surrounding the luminescent area 121 and the n-type electrode 113. A plurality of gaps 120 is disposed among the plurality of protrusions 119. FIG. 3 is a cross-sectional view along line A-A′ of FIG. 2. A transparent conductive layer 109 is formed on the luminescent area 121. A p-type electrode 114 is formed on the transparent conductive layer 109. An n-type electrode 113 is formed on the n-type conduction layer 104 and beside the luminescent area 121. The plurality of protrusions 119 are formed on the device-dicing surface 118 and are separated from each other by a plurality of grooves 120. A protection layer 115 covers the luminescent area 121 and the plurality of protrusions 119. Because light is non-directional and photons are dispersed on the luminescent area, a majority of the light can be directed to emit externally by changing the reflection angle of the light using the angle and height of the protrusion. However, the photons may not be allowed to pass through the gaps, resulting in total reflection or refraction, and generating heat.

Thus, the present invention proposes a new approach to resolve the above-mentioned issues so as to improve the light extraction efficiency of a semiconductor optoelectronic device.

### SUMMARY OF THE INVENTION

According to the discussion in the Description of the Related Art and to meet the requirements of industry, the present invention provides a semiconductor optoelectronic device, including a structure which is etched to form a first luminescent area as a major luminescent area and a second luminescent area as a secondary luminescent area. A plurality of holes is formed on the second luminescent area, which may surround the first luminescent area. A transparent conductive layer covers the first luminescent area and the second luminescent area.

One objective of the present invention is to increase the light emitting area of a semiconductor optoelectronic device.

Another objective of the present invention is to improve the light extraction efficiency of a semiconductor optoelectronic device.

To better understand the above-described objectives, characteristics and advantages of the present invention, embodiments, with reference to the drawings, are provided for detailed explanations.

### BRIEF DESCRIPTION OF THE DRAWINGS

The invention will be described according to the appended drawings in which:

FIGS. 1A and 1B respectively show two conventional devices including light emitting regions etched to different depths;

FIG. 2 is a top view showing a semiconductor optoelectronic device of a coplanar electrode configuration;

FIG. 3 is a cross-sectional view along line A-A′ of FIG. 2;

FIG. 4 is a top view showing a semiconductor optoelectronic device of a coplanar electrode configuration according to one embodiment of the present invention;

FIGS. 5A to 5G are cross-sectional views showing a method for forming a semiconductor optoelectronic device of separated coplanar electrode type according to one embodiment of the present invention;

FIG. 6 is a cross-sectional view showing a plurality of holes according to one embodiment of the present invention;

FIG. 7 is a top view showing a semiconductor optoelectronic device of a double-sided electrode configuration according to one embodiment of the present invention;

FIG. 8 is a cross-sectional view taken along line C-C′ of FIG. 7; and

FIGS. 9A to 9E are cross-sectional views showing a method for forming a semiconductor optoelectronic device of separated double-sided electrode configuration according to one embodiment of the present invention.

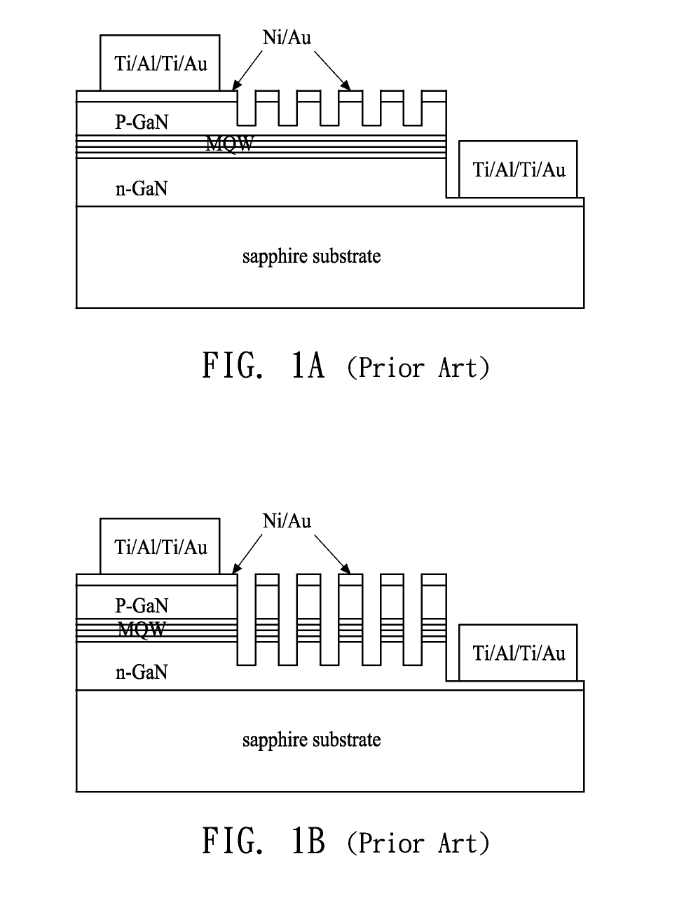

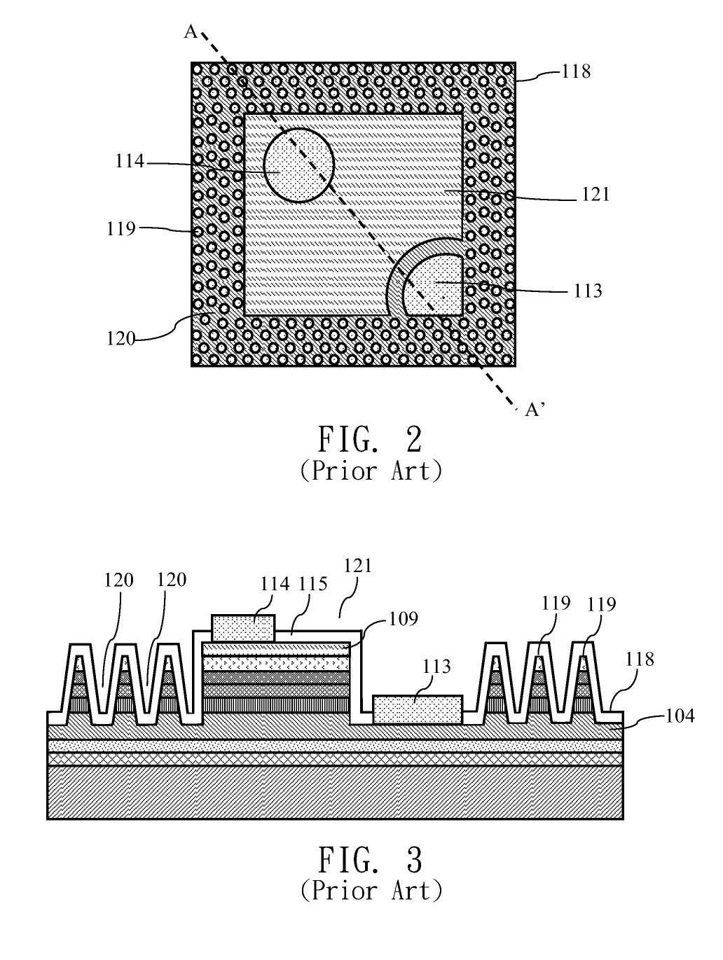

### DETAILED DESCRIPTION OF THE INVENTION

The present invention exemplarily demonstrates embodiments of a semiconductor optoelectronic device with enhanced light extraction efficiency and a fabricating method for forming the same. In order to thoroughly understand the present invention, detailed descriptions of method steps and components are provided below. Clearly, the implementations of the present invention are not limited to the specific details that are familiar to persons in the art related to optoelectronic semiconductor manufacturing processes to avoid unnecessary limitations to the present invention. On the other hand, components or method steps that are well known are not described in detail. A preferred embodiment of the present invention will be described in detail as follows. However, in addition to the preferred detailed description, other embodiments can be broadly employed, and the scope of the present invention is not limited by any of the embodiments, but should be defined in accordance with the following claims and their equivalents.

The semiconductor optoelectronic structure of the embodiments of the present invention can be manufactured by initially forming an epitaxial layer, which is then etched to obtain a first luminescent area, namely a major luminescent area, and a second luminescent area, namely a secondary luminescent area. The second luminescent area may surround the first luminescent area and comprise a plurality of holes. Due to the directionless propagation of light, light generated by the luminescent layer of the first and second luminescent areas can be transmitted not only through and out of the p-type conduction layer, but also in an internal direction or a lateral direction out of a semiconductor optoelectronic device. Such internal reflection and refraction through and out of the plurality of holes not only increases the luminance of the semiconductor optoelectronic device, but also improve the light extraction efficiency.

According to one embodiment of the present invention, a semiconductor optoelectronic device with enhanced light extraction efficiency comprises a substrate, a first luminescent area, and a second luminescent area. The second luminescent area can surround the first luminescent area and comprise a plurality of holes.

The first and second luminescent areas may comprise an n-type conduction layer formed on the substrate. A luminescent layer can be formed on the n-type conduction layer. A p-type conduction layer can be formed on the luminescent layer. A transparent conductive layer can be formed on the p-type conduction layer.

A buffer layer can be disposed between the substrate and the n-type conduction layer. A protection layer can cover the first luminescent area and the second luminescent area while exposing a p-type electrode, or can cover the first luminescent area and the second luminescent area while exposing the p-type electrode and an n-type electrode.

The n-type conduction layer may comprise silicon dopants, and the p-type conduction layer may comprise magnesium dopants.

The n-type electrode can electrically connect to the n-type conduction layer, and the p-type electrode can electrically connect to the p-type conduction layer.

The hole may have a diameter of from 0.1 to 10 micrometers. The height of the hole can be between that of the p-type conduction layer and that of the n-type conduction layer. The hole may include a roughened side surface.

The above-mentioned substrate can be a sapphire (Al₂O₃) substrate, a silicon carbide (SiC) substrate, a lithium aluminate (LiAlO₂) substrate, a lithium gallates (LiGaO₂) substrate, a silicon substrate, a gallium nitride (GaN) substrate, a zinc oxide (ZnO) substrate, an aluminum zinc oxide (AlZnO) substrate, a gallium arsenide (GaAs) substrate, a gallium phosphide (GaP) substrate, a gallium antimonide (GaSb) substrate, an indium phosphide (InP) substrate, an indium arsenide (InAs) substrate, or a zinc selenide (ZnSe) substrate.

The above-mentioned buffer layer can be of gallium nitride, aluminum gallium nitride, aluminum nitride, or InₓGa₁₋ₓN/In_{y}Ga_{1-y}N supperlattice material, wherein x≠y.

The transparent conductive layer may be nickel-gold (Ni/Au) alloy, indium tin oxide, indium zinc oxide, indium tungsten oxide, or indium gallium oxide.

Furthermore, the present invention proposes a method for forming a semiconductor optoelectronic device with enhanced light extraction efficiency. The method comprises the steps of: providing a substrate; forming a luminescent structure on the substrate; and etching the luminescent structure to form a first luminescent area and a second luminescent area, wherein the second luminescent area comprises a plurality of holes and surrounds the first luminescent area.

The above-mentioned luminescent structure may comprise an n-type conduction layer formed on the substrate, a luminescent layer formed on the n-type conduction layer, a p-type conduction layer formed on the luminescent layer, and a transparent conductive layer disposed on the p-type conduction layer.

A buffer can be formed between the substrate and the n-type conduction layer. A protection layer can cover the first and second luminescent areas while exposing a p-type electrode, or can cover the first and second luminescent areas while exposing the p-type electrode and an n-type electrode.

The above-mentioned forming steps are explained by the following figures each showing the corresponding structure and the descriptions describing the corresponding figure.

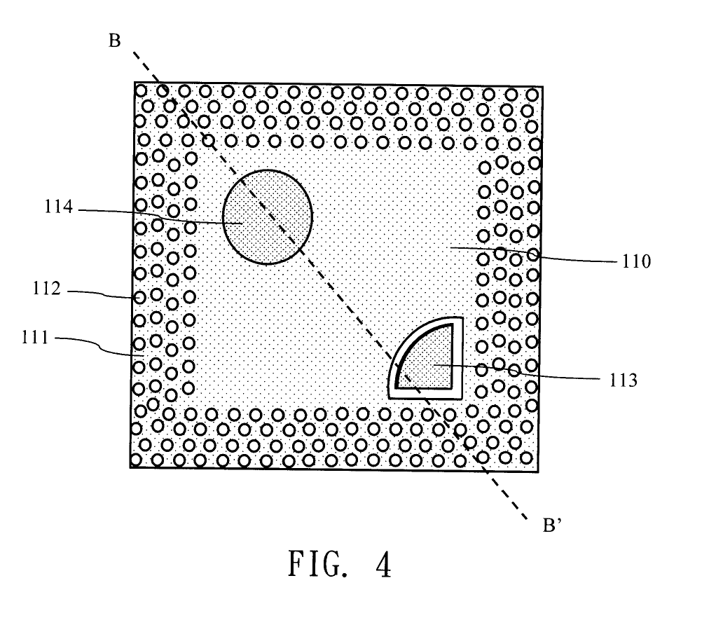

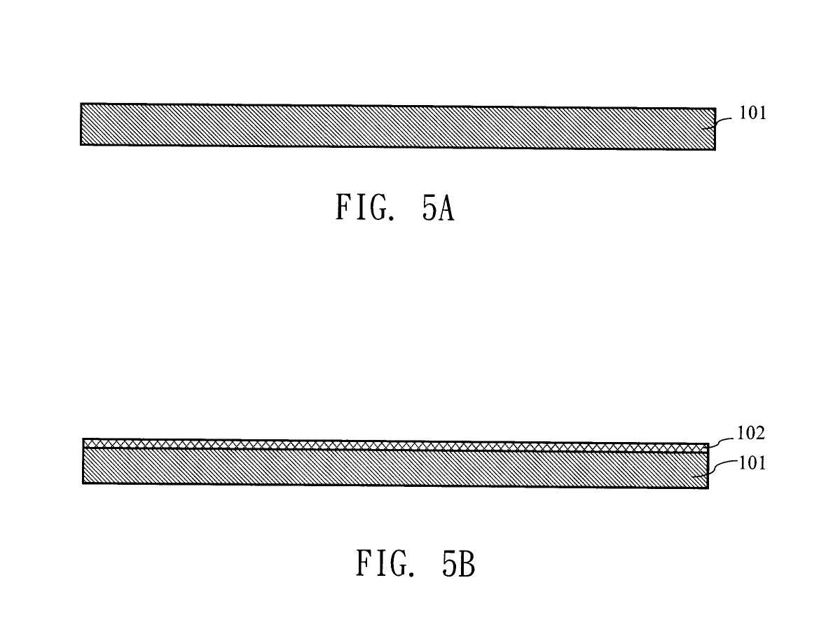

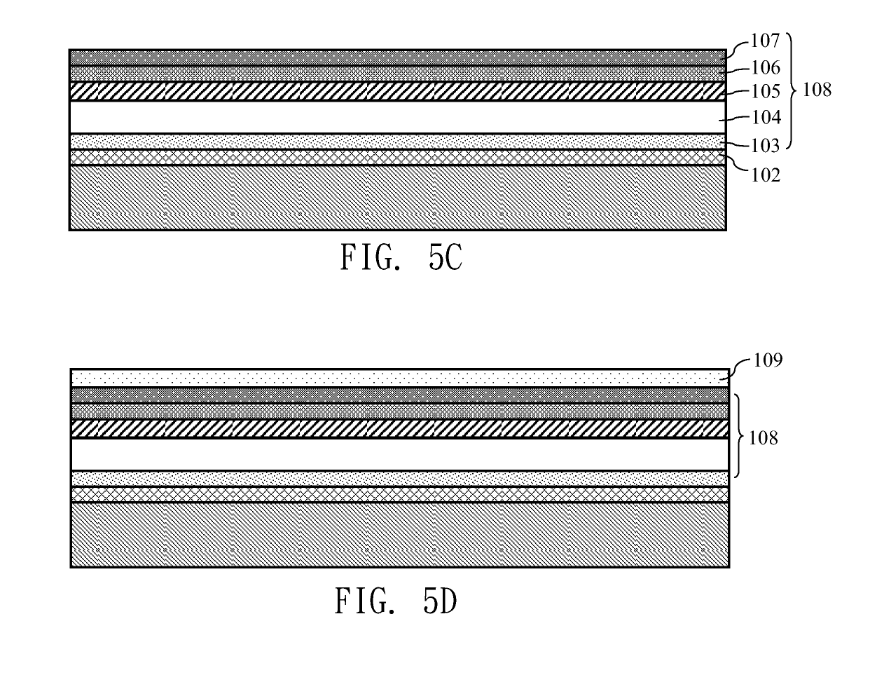

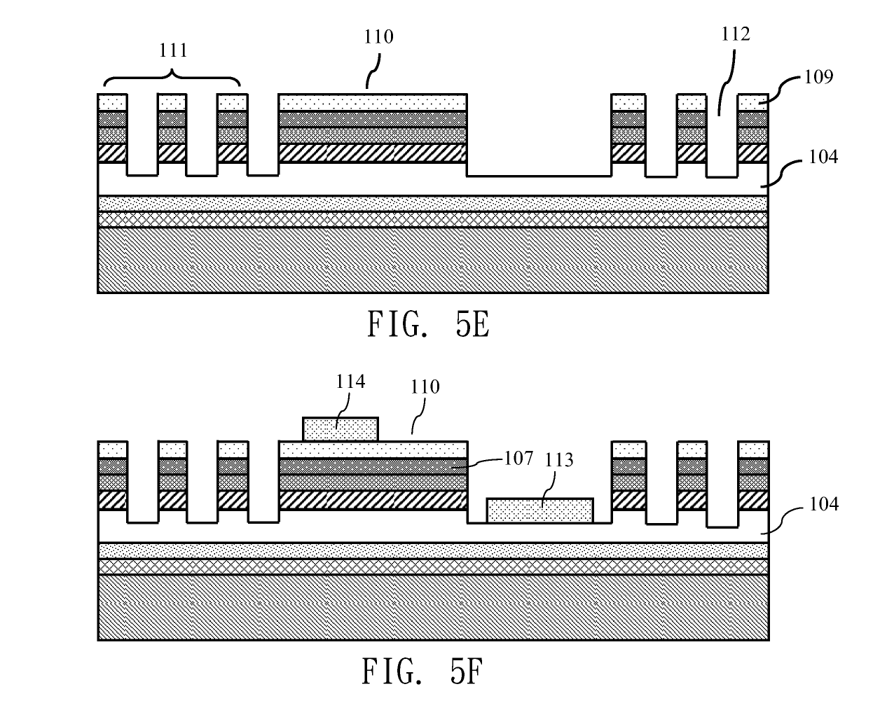

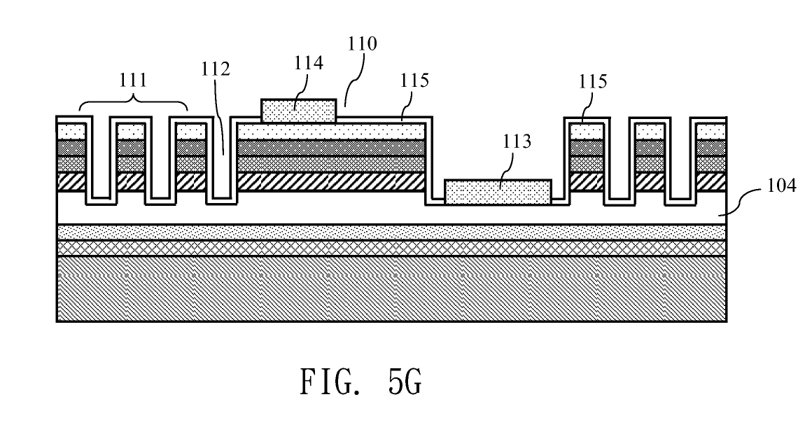

FIG. 4 is a top view showing a semiconductor optoelectronic device of a coplanar electrode configuration. On the first luminescent area 110 of the semiconductor optoelectronic device, a p-type electrode 114 is formed. Next to the first luminescent area 110, an n-type electrode 113 is formed. A second luminescent area 111 surrounds the first luminescent area 110 and the n-type electrode 113, and comprises a plurality of holes 112. FIGS. 5A to 5G are cross sections along line B-B′ of FIG. 4, and each cross section demonstrates the structure formed in the corresponding process step.

As shown in FIG. 5A, the surfaces of a substrate 101 are cleaned. A substrate 101 such as a sapphire (Al₂O₃) substrate, a silicon carbide (SiC) substrate, a lithium aluminate (LiAlO₂) substrate, a lithium gallates (LiGaO₂) substrate, a silicon substrate, a gallium nitride (GaN) substrate, a zinc oxide (ZnO) substrate, an aluminum zinc oxide (AlZnO) substrate, a gallium arsenide (GaAs) substrate, a gallium phosphide (GaP) substrate, a gallium antimonide (GaSb) substrate, an indium phosphide (InP) substrate, an indium arsenide (InAs) substrate, or a zinc selenide (ZnSe) substrate is provided. The cleaning of the substrate 101 can be performed by a thermal cleaning process in which the substrate 101 is exposed in a hydrogen environment at 1200 degrees Celsius, and ammonia gas and an organic metal precursor are introduced. The organic metal precursor can be an aluminum organic metal precursor such as trimethylaluminum and triethylaluminum, a gallium organic metal precursor such as trimethylgallium and triethylgallium, or an indium organic metal precursor such as trimethylindium and triethylindiuim.

As shown in FIG. 5B, a buffer layer 102 is formed on the substrate 101. The lattice structure and lattice constant are important factors for selection of an epitaxial substrate. If the difference between the lattice constants of a substrate and an epitaxial layer is too great, a buffer layer is required to obtain an epitaxial layer of better quality. The buffer layer 102 can be formed using a chemical vapor deposition process performed by metal organic chemical vapor deposition equipment or molecular beam epitaxy equipment so that the epitaxial layer can be grown at a lower temperature compared to a normal epitaxial layer growing process performed later. For example, aluminum gallium indium nitride layers are normally grown at a temperature between 800 and 1400 degrees Celsius; in contrast, the buffer layer 102 is grown at a temperature between 250 and 700 degrees Celsius. When a metal organic chemical vapor deposition process is applied, the nitrogen precursor can be ammonia (NH₃) or nitrogen; the gallium precursor can be trimethylgallium or triethylaliuminum; the aluminum precursor can be trimethylaluminum or triethylaluminum; and the indium precursor can be trimethylindium or triethylindium. The reactor may be maintained at low pressure or ambient pressure. The buffer layer 102 can be of gallium nitride, aluminum gallium nitride, aluminum nitride, or InₓGa₁₋ₓN/In_{y}Ga_{1-y}N supperlattice material, while x≠y. For details on the formation of the buffer layer made of InₓGa₁₋ₓN/In_{y}Ga_{1-y}N supperlattice material, please refer to Taiwan Patent Application No. 096104378.

As shown in FIG. 5C, after formation of the buffer layer 102, a luminescent structure 108 is epitaxially formed on the buffer layer 102. To improve the quality of the grown epitaxial lattice of the luminescent structure, a non-doped gallium nitride layer 103 or aluminum gallium nitride layer can be formed on the buffer layer 102 in advance. After formation of a non-doped gallium nitride layer 103, group IV atoms are implanted to form an n-type conduction layer 104. In the present embodiment, the group IV atom can be a silicon atom. The silicon precursor in the metal organic chemical vapor deposition equipment can be silane (SiH₄) or disilane (Si₂H₆). The n-type conduction layer 104 is sequentially composed of a gallium nitride layer or an aluminum gallium nitride doped with highly concentrated silicon and a gallium nitride layer or an aluminum gallium nitride doped with minimally concentrated silicon. The gallium nitride layer or the aluminum gallium nitride doped with highly concentrated silicon can provide an ohmic contact to an n-type semiconductor.

Thereafter, a luminescent layer 105 is formed on the n-type conduction layer 104, wherein the luminescent layer 105 can be a single hetero-structure, a double hetero-structure, a single quantum well layer, or a multiple quantum well layer. In the present invention, a multiple quantum well layer structure, namely a multiple quantum well layer/barrier layer structure, is adopted. The quantum well layer can be of indium gallium nitride, and the barrier layer can be made of a ternary alloy such as aluminum gallium nitride. Further, a quaternary alloy such as AlₓIn_{y}Ga_{1-x-y}N can be used for formation of the quantum well layer and the barrier layer, wherein the barrier layer with a wide band gap and the quantum well layer with a narrow band gap can be obtained by adjusting the concentrations of aluminum and indium in the aluminum indium gallium nitride. The luminescent layer 105 can be doped with an n-type or p-type dopant, or can be doped with an n-type and p-type dopants simultaneously, or can include no dopants. In addition, the quantum well layer can be doped and the barrier layer can be not doped; the quantum well layer can be not doped and the barrier layer can be doped; both the quantum well layer and the barrier layer can be doped; or neither the quantum well layer nor the barrier layer can be doped. Further, a portion of the quantum well layer can be delta-doped.

Next, an electron barrier layer 106 of p-type conduction is formed on the luminescent layer 105. The electron barrier layer 106 of p-type conduction may comprise a first Group III-V semiconductor layer and a second Group III-V semiconductor layer. The first and second Group III-V semiconductor layers can have two different band gaps, and are periodically and repeatedly deposited on the luminescent layer 105. The periodical and repeated deposition process can form an electron barrier layer having a wider band gap, which is higher than that of the active luminescent layer, so as to block excessive electrons overflowing from the luminescent layer 105. The first Group III-V semiconductor layer can be an aluminum indium gallium nitride (AlₓIn_{y}Ga_{1-x-y}N) layer. The second Group III-V semiconductor layer can be an aluminum indium gallium nitride (AlᵤInᵥGa₁₋ᵤ₋ᵥN) layer, wherein 0<x≦1, 0≦y<1, x+y≦1, 0≦u<1, 0≦v≦1, and u+v≦1. When x is equal to u, y is not equal to v. Further, the first and second Group III-V semiconductor layers can be of gallium nitride, aluminum nitride, indium nitride, aluminum gallium nitride, indium gallium nitride, or aluminum indium nitride.

Finally, a Group II atom is doped to form a p-type conduction layer 107 on the electron barrier layer 106. In the present embodiment, the Group II atom can be a magnesium atom. The magnesium precursor in the metal organic chemical vapor deposition equipment can be CP₂Mg. The p-type conduction layer 107 is sequentially composed of a gallium nitride layer or an aluminum gallium nitride doped with minimally concentrated magnesium and a gallium nitride layer, or an aluminum gallium nitride doped with highly concentrated magnesium. The gallium nitride layer or the aluminum gallium nitride doped with highly concentrated magnesium can provide an ohmic contact to a p-type semiconductor.

As shown in FIG. 5D, a transparent conductive layer 109 is formed on the luminescent structure 108. The transparent conductive layer 109 can have a high transmission rate and high electrical conductivity so that light can transmit therethrough and electrical current can be uniformly dispersed. Generally, the transparent conductive layer 109 can be formed on the luminescent structure 108 using physical vapor deposition such as evaporation or sputtering. The material of the transparent conductive layer 109 can be nickel gold alloy, indium tin oxide, indium zinc oxide, indium tungsten oxide, or indium gallium oxide.

As shown in FIG. 5E, after the formation of the transparent conductive layer 109, a photoresist film is completely formed on the surface of the transparent conductive layer 109 by centrifugally spinning photoresist on the surface using a photoresist coater. Next, the photoresist film is patterned using a photolithography process to obtain a mask such that a portion of the transparent conductive layer 109 is exposed for etching. Inductively coupled plasma etcher is used to etch out a first luminescent area 110, a second luminescent area 111, a plurality of holes 112 disposed on the second luminescent area 111, and to expose the n-type conduction layer 104, wherein the second luminescent area 111 and the plurality of holes 112 surround the first luminescent area 110. Finally, the photoresist film is removed.

As shown in FIG. 5F, a p-type electrode 114 is formed on the first luminescent area 110 and electrically connected to the p-type conduction layer 107, and an n-type electrode 113 is electrically connected to the n-type conduction layer 104. The material of the p-type electrode 114 can be nickel gold alloy, platinum gold alloy, tungsten, chrome-gold alloy, or palladium. The material of the n-type electrode can be titanium/aluminum/titanium/gold, chrome-gold alloy, or lead-gold alloy.

As shown in FIG. 5G, a protection layer 115 is finally formed to cover the first luminescent area 110 and the second luminescent area 111 but exposes the p-type electrode 114 and the n-type electrode 113 for electrical connection. The protection layer 115 protects the first luminescent area 110 and the second luminescent area 111 from external pollutants, which can cause the semiconductor optoelectronic device to fail. The material of the protection layer 115 can be silicon oxide or silicon nitride.

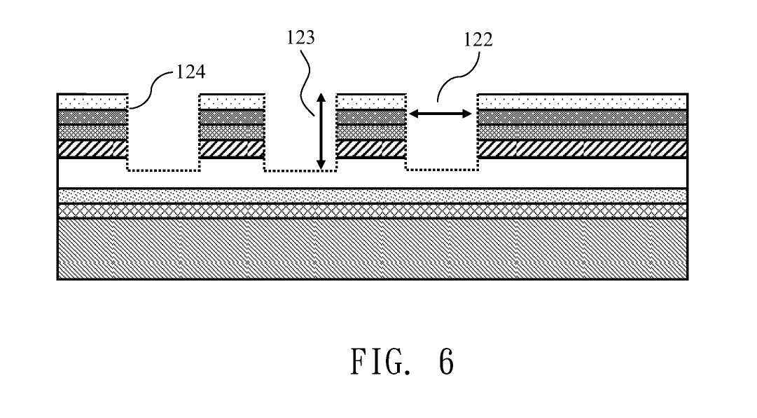

The detailed characteristics of the hole 112 are explained hereinafter. FIG. 6 is a cross-sectional view showing a plurality of holes 112 according to one embodiment of the present invention. The hole 112 has a diameter 122 of from 0.1 to 10 micrometers. The height 123 of the hole 112 can be between the height of the p-type conduction layer 107 and the height of the n-type conduction layer 104. The side surface 124 of the hole 112 can be a roughened surface for refracting light.

Generally, the substrate 101 can be a sapphire (Al₂O₃) substrate; however, the sapphire substrate has disadvantages such as poor electrical conductivity and low heat dissipation efficiency, which may detrimentally affect the reliability of the semiconductor optoelectronic device. To mitigate such factors affecting the reliability of the semiconductor optoelectronic device, a substrate such as a silicon carbide (SiC) substrate, a silicon substrate, a gallium nitride (GaN) substrate, a gallium arsenide (GaAs) substrate, a gallium phosphide (GaP) substrate, a gallium antimonide (GaSb) substrate, an indium phosphide (InP) substrate, an indium arsenide (InAs) substrate, or a zinc selenide (ZnSe) substrate, having better electrical conductivity and heat dissipation efficiency, is preferably used to form a semiconductor optoelectronic device of a double-sided electrode configuration.

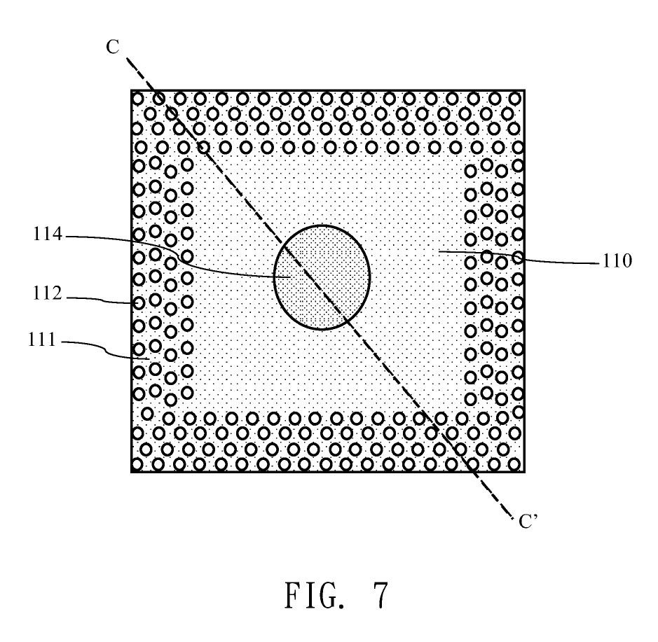

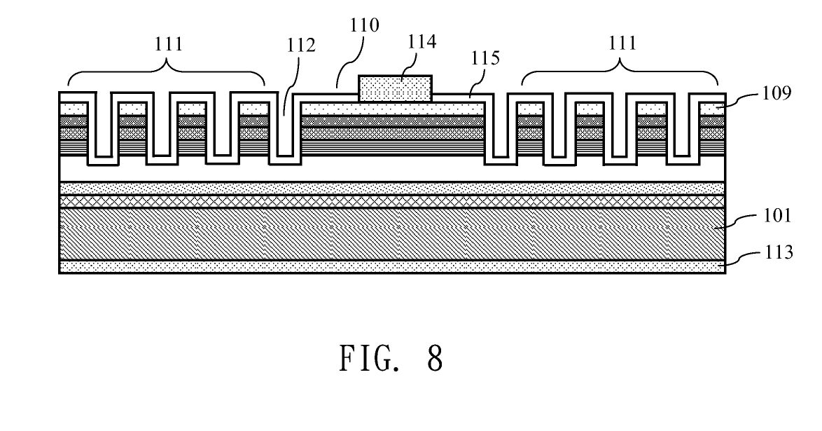

FIG. 7 is a top view showing a semiconductor optoelectronic device of a double-sided electrode configuration according to one embodiment of the present invention. On a first luminescent area 110, a p-type electrode 114 is formed. A second luminescent area 111 surrounds the first luminescent area 110 and comprises a plurality of holes 112. FIG. 8 is a cross-sectional view taken along line C-C′ of FIG. 7. A transparent conductive layer 109 is formed on a first luminescent area 110 and a second luminescent area 111. The second luminescent area 111 can comprise a plurality of holes 112, and can surround the first luminescent area 110. A p-type electrode 114 is formed on the transparent conductive layer 109. An n-type electrode 113 is disposed below the substrate 101. Finally, a protection layer 115 covers the first luminescent area 110 and the second luminescent area 111, while exposing the p-type electrode 114 for electrical connection.

In addition, the process of epitaxially growing a semiconductor layer may cause the semiconductor layer to exhibit threading dislocation and thermal stress issues because the lattice constant and the thermal expansion coefficient of the semiconductor layer and the heterogeneous substrate are different. Thus, the present invention provides another fabricating method in which a substrate separation technique is applied to mitigate the above-mentioned issues so as to increase the stability of a semiconductor optoelectronic device.

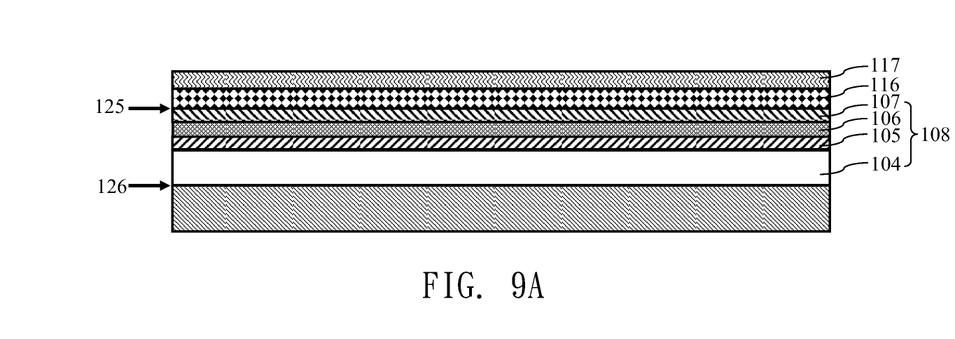

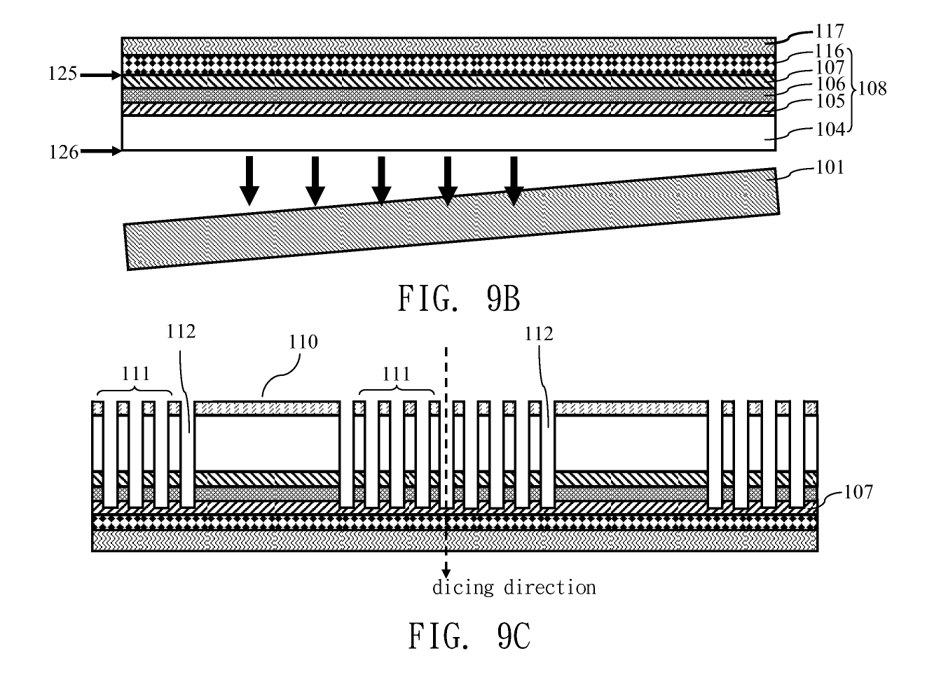

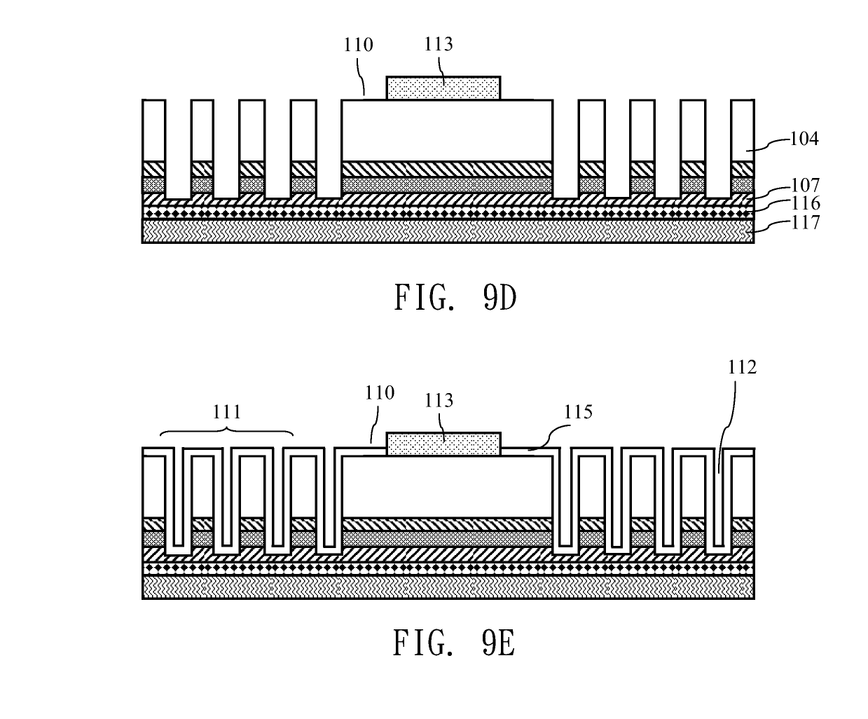

The below-mentioned substrate separation methods are disclosed in patent applications assigned to Advanced Optoelectronic Technology, Inc. The substrate and the luminescent structure are initially separated, and a luminescent area and a plurality of holes are formed using an etching process. The process steps of fabricating a semiconductor optoelectronic device with enhanced light extraction efficiency are shown in FIGS. 9A to 9E. The process steps begin with an etching process, and to avoid redundancy, the substrate separation technique is not described herein.

The first substrate separation method initially grows a first Group III nitride compound semiconductor layer on a surface of a temporary substrate. The first Group III nitride compound semiconductor layer can be patterned using lithographic and etching processes. A second Group III nitride compound semiconductor layer is formed on the first Group III nitride compound semiconductor layer. A conductive layer is formed on the second Group III nitride compound semiconductor layer. The combination of the second Group III nitride compound semiconductor layer and the conductive layer can be obtained by separating the combination from the temporary substrate using the first Group III nitride compound semiconductor layer. The details and steps of the separation process used in the first substrate separation method are described in Taiwan Patent Application No. 097107609 assigned to Advanced Optoelectronic Technology, Inc.

The second substrate separation method initially grows a first Group III nitride compound semiconductor layer on a surface of a primary substrate. An epitaxial blocking layer is formed on the first Group III nitride compound semiconductor layer. A second Group III nitride compound semiconductor layer is formed on the epitaxial blocking layer and the uncovered portion of the first Group III nitride compound semiconductor layer. The epitaxial blocking layer is then removed. A third Group III nitride compound semiconductor layer is formed on the second Group III nitride compound semiconductor layer. A conductive layer is deposited on the third Group III nitride compound semiconductor layer. Finally, the third Group III nitride compound semiconductor layer and the structure thereon are separated from the second Group III nitride compound semiconductor layer. The details and steps of the separation process used in the second substrate separation method are described in Taiwan Patent Application No. 097115512 assigned to Advanced Optoelectronic Technology, Inc.

The third substrate separation method initially forms a mask on a substrate, and the mask is annealed to obtain a plurality of pillar elements. A plurality of pillar elements is formed on the substrate by etching the substrate via the gaps between the plurality of pillar elements. The plurality of mask elements are separated from the substrate to obtain a substrate with a plurality of pillar elements, wherein the plurality of the pillar elements can be a pillar element array. Thereafter, a semiconductor layer is formed on the pillar element array, and the pillar element array is wet-etched to separate the semiconductor layer and the substrate so as to obtain a freestanding block material or a thin film. The details and steps of the separation process used in the third substrate separation method are described in Taiwan Patent Application No. 097117099 assigned to Advanced Optoelectronic Technology, Inc.

The process method provided by the present invention, subsequent to the second substrate separation method, is described as follows. Referring to FIG. 9A, a conductive layer 117 is formed on the first surface 125 of the luminescent structure 108 using an electroplating or composite-electroplating method. Between the luminescent structure 108 and the conductive layer 117, a metal layer 116 can be formed. The material of the conductive layer 117 can be copper, nickel, or copper-tungsten alloy. The luminescent structure 108 may comprise an n-type conduction layer 104, a luminescent layer 105, an electron blocking layer 106, and a p-type conduction layer 107, wherein the first surface 125 of the luminescent structure 108 is that of the p-type conduction layer 107, and the second surface 126 opposite the first surface 125 is that of the n-type conduction layer 104.

Referring to FIGS. 9B and 9C, after the separation of the substrate 101 and the luminescent structure 108, a photoresist film is formed on the surface of the luminescent structure 108 by centrifugally spinning photoresist on the surface using a photoresist coater. A mask is formed by patterning the photoresist film using photolithography so that the portions for etching can be exposed. Inductively coupled plasma etcher is used to etch out a first luminescent area 110, a second luminescent area 111, and a plurality of holes 112, while exposing the p-type conduction layer 107, wherein the second luminescent area 111 and the plurality of holes 112 surround the first luminescent area 110. Simultaneously, optoelectronic chips are separated from each other so that they can be diced. Finally, the photoresist film is removed.

Referring to FIG. 9D, an n-type electrode 113 is formed on the first luminescent area 110 and electrically connected to the n-type conduction layer 104. The p-type conduction layer 107 is electrically connected via the metal layer 116 and the conductive layer 117. The material of the n-type electrode 113 can be titanium/aluminum/titanium/gold, chrome-gold alloy, or lead-gold alloy.

Referring to FIG. 9E, a protection layer 115 is formed to cover the first luminescent area 110 and the second luminescent area 111 while exposing the n-type electrode 113 so as to protect the first luminescent area 110 and the second luminescent area 111 from external pollutants. The material of the protection layer 115 can be silicon oxide or silicon nitride.

The hole 112 is similar to that formed in a semiconductor optoelectronic device of a coplanar electrode configuration. FIG. 6 is a cross-sectional view showing a plurality of holes 112 according to one embodiment of the present invention. The hole 112 has a diameter 122 of from 0.1 to 10 micrometers. The height 123 of the hole 112 can be between the height of the p-type conduction layer 107 and the height of the n-type conduction layer 104. The side surface 124 of the hole 112 can be a roughened surface for refracting light.

The above-described embodiments of the present invention are intended to be illustrative only. Numerous alternative embodiments may be devised by persons skilled in the art without departing from the scope of the following claims.

What is claimed is:

1. A semiconductor optoelectronic device with enhanced light extraction efficiency, comprising:
a substrate;
a first luminescent area; and
a second luminescent area including a plurality of holes surrounding said first luminescent area, each of said first luminescent area and said second luminescent area comprising:
an n-type conduction layer disposed on said substrate;
a luminescent layer formed on said n-type conduction layer;
a p-type conduction layer formed on said luminescent layer; and
a transparent conductive layer disposed on said p-type conduction layer.

2. The semiconductor optoelectronic device with enhanced light extraction efficiency of claim 1, further comprising a buffer layer formed between said substrate and said n-type conduction layer.

3. The semiconductor optoelectronic device with enhanced light extraction efficiency of claim 2, wherein said buffer layer is gallium nitride, aluminum gallium nitride, aluminum nitride, or InₓGa₁₋ₓN/In_{y}Ga_{1-y}N while x≠y.

4. The semiconductor optoelectronic device with enhanced light extraction efficiency of claim 1, wherein said transparent conductive layer is nickel gold alloy, indium tin oxide, indium zinc oxide, indium tungsten oxide, or indium gallium oxide.

5. The semiconductor optoelectronic device with enhanced light extraction efficiency of claim 1, further comprising a p-type electrode electrically connecting to said p-type conduction layer and a protection layer covering said first luminescent area and said second luminescent area, while exposing said p-type electrode.

6. The semiconductor optoelectronic device with enhanced light extraction efficiency of claim 1, further comprising a p-type electrode electrically connecting to said p-type conduction layer, an n-type electrode electrically connecting to said n-type conduction layer and a protection layer covering said first luminescent area and said second luminescent area, while exposing said p-type electrode and said n-type electrode.

7. The semiconductor optoelectronic device with enhanced light extraction efficiency of claim 6, wherein said protection layer is silicon oxide or silicon nitride.

8. The semiconductor optoelectronic device with enhanced light extraction efficiency of claim 1, wherein said hole has a diameter of from 0.1 to 10 micrometers.

9. The semiconductor optoelectronic device with enhanced light extraction efficiency of claim 8, wherein the height of said hole is between the height of said p-type conduction layer and the height of said n-type conduction layer.

10. The semiconductor optoelectronic device with enhanced light extraction efficiency of claim 9, wherein said hole includes a roughened side surface.

11. A method for forming a semiconductor optoelectronic device with enhanced light extraction efficiency, comprising the steps of:
providing a substrate;
forming a luminescent structure on said substrate, said luminescent structure comprising:
an n-type conduction layer formed on said substrate;
a luminescent layer formed on said n-type conduction layer; and
a p-type conduction layer formed on said luminescent layer; and
etching said luminescent structure to form a first luminescent area and a second luminescent area including a plurality of holes surrounding said first luminescent area.

12. The method of claim 11, further comprising a step of forming a buffer layer between said substrate and said n-type conduction layer.

13. The method of claim 12, wherein said buffer layer is gallium nitride, aluminum gallium nitride, aluminum nitride, or InₓGa₁₋ₓN/In_{y}Ga_{1-y}N while x≠y.

14. The method of claim 11, wherein said transparent conductive layer is nickel gold alloy, indium tin oxide, indium zinc oxide, indium tungsten oxide, or indium gallium oxide.

15. The method of claim 11, further comprising a step of forming a p-type electrode electrically connecting to said p-type conduction layer and a protection layer covering said first luminescent area and said second luminescent area, while exposing said p-type electrode.

16. The method of claim 11, further comprising a step of forming a p-type electrode electrically connecting to said p-type conduction layer, an n-type electrode electrically connecting to said n-type conduction layer and a protection layer covering said first luminescent area and said second luminescent area, while exposing said p-type electrode and said n-type electrode.

17. The method of claim 16, wherein said protection layer is silicon oxide or silicon nitride.

18. The method of claim 11, wherein said hole has a diameter of from 0.1 to 10 micrometers.

19. The method of claim 18, wherein the height of said hole is between the height of said p-type conduction layer and the height of said n-type conduction layer.

20. The method of claim 19, wherein said hole includes a roughened side surface.
